(19) United States
(12) Patent Application Publication
(10) Pub. No.: US 2019/0081028 A1
(43) Pub. Date: Mar. 14, 2019

(54) OPTICAL MODULE, MODULE, AND METHODS FOR MANUFACTURING OPTICAL MODULE AND MODULE

(71) Applicant: MITSUMI ELECTRIC CO., LTD., Tokyo (JP)

(72) Inventors: Toshiki KOMIYAMA, Tokyo (JP); Makoto KITAZUME, Tokyo (JP); Tadashi ONO, Tokyo (JP); Yuki INUGAI, Tokyo (JP)

(73) Assignee: MITSUMI ELECTRIC CO., LTD., Tokyo (JP)

(21) Appl. No.: 16/093,684

(22) PCT Filed: May 1, 2017
(86) PCT No.: PCT/JP2017/017170

§ 371 Date: Oct. 15, 2018

(30) Foreign Application Priority Data
May 30, 2016 (JP) 2016-107497

(51) Int. Cl. H01L 25/16; H05K 1/02; G02B 1/11

(52) U.S. Cl. CPC H01L 25/167; G02B 1/11; H05K 1/0274

(57) ABSTRACT

An optical module includes a wiring substrate; an optical element mounted on the wiring substrate; a first light-transmitting body mounted on an upper surface of the optical element; and a light-shielding resin covering the optical element and a side surface portion of the first light-transmitting body, wherein the light-shielding resin includes filler, an upper surface of the light-shielding resin is a ground surface, and a ground surface of the filler is exposed on the upper surface of the light-shielding resin.

### TECHNICAL FIELD

The present invention relates to an optical module, a module, and methods for manufacturing an optical module and a module.

### BACKGROUND ART

Conventionally, an optical module in which a semiconductor light-receiving element is mounted on a package substrate, and which is partially sealed with a non-translucent resin so as to secure an optical path, is known (for example, refer to Patent Literature 1).

In such an optical module, for example, the sealing process is performed by a potting method. However, according to the potting method, molding pressure cannot be applied, so there is a concern about degradation of resin filling properties and generation of voids. Furthermore, due to the surface tension in the formation process, the flatness of the upper surface of the resin may be degraded. If the flatness of the upper surface of the resin is degraded, this will be a problem when mounting a component on the surface of the resin, etc.

### CITATION LIST

### Patent Literature

### [PTL 1]

Japanese Unexamined Patent Application Publication No. 2014-154629

### SUMMARY OF INVENTION

### Technical Problem

The present invention has been made in view of the above points, and an object of the present invention is to provide an optical module in which the flatness of the upper surface of a resin, covering an element to be mounted, is improved.

### Solution to Problem

It is required that an optical module (1) includes a wiring substrate (10); an optical element (20) mounted on the wiring substrate (10); a first light-transmitting body (30) mounted on an upper surface of the optical element (20); and a light-shielding resin (50) covering the optical element (20) and a side surface portion of the first light-transmitting body (30), wherein the light-shielding resin (50) includes filler, an upper surface of the light-shielding resin (50) is a ground surface, and a ground surface of the filler is exposed on the upper surface of the light-shielding resin (50).

Note that the reference numerals in parentheses are provided for easy understanding, and are merely examples, and the present invention is not limited to the illustrated embodiments.

### Advantageous Effects of Invention

According to the disclosed technology, it is possible to provide an optical module in which the flatness of the upper surface of a resin, covering an element to be mounted, is improved.

### BRIEF DESCRIPTION OF DRAWINGS

FIG. 1A is a cross-sectional view of an example of an optical module according to a first embodiment.

FIG. 1B is a plan view of an example of the optical module according to the first embodiment.

FIG. 2A is a diagram (part 1) illustrating an example of the manufacturing process of the optical module according to the first embodiment.

FIG. 2B is a diagram (part 2) illustrating an example of the manufacturing process of the optical module according to the first embodiment.

FIG. 2C is a diagram (part 3) illustrating an example of the manufacturing process of the optical module according to the first embodiment.

FIG. 2D is a diagram (part 4) illustrating an example of the manufacturing process of the optical module according to the first embodiment.

FIG. 2E is a diagram (part 5) illustrating an example of the manufacturing process of the optical module according to the first embodiment.

FIG. 2F is a diagram (part 6) illustrating an example of the manufacturing process of the optical module according to the first embodiment.

FIG. 3A is a diagram (part 7) illustrating an example of the manufacturing process of the optical module according to the first embodiment.

FIG. 3B is a diagram (part 8) illustrating an example of the manufacturing process of the optical module according to the first embodiment.

FIG. 3C is a diagram (part 9) illustrating an example of the manufacturing process of the optical module according to the first embodiment.

FIG. 3D is a diagram (part 10) illustrating an example of the manufacturing process of the optical module according to the first embodiment.

FIG. 4A is a perspective view (part 1) of an example of an optical module according to a second embodiment.

FIG. 4B is a perspective view (part 2) of an example of the optical module according to the second embodiment.

FIG. 5 is a cross-sectional view of an example of an optical module according to a third embodiment.

FIG. 6A is a diagram (part 1) illustrating an example of the manufacturing process of the optical module according to the third embodiment.

FIG. 6B is a diagram (part 2) illustrating an example of the manufacturing process of the optical module according to the third embodiment.

FIG. 6C is a diagram (part 3) illustrating an example of the manufacturing process of the optical module according to the third embodiment.

FIG. 6D is a diagram (part 4) illustrating an example of the manufacturing process of the optical module according to the third embodiment.

FIG. 7 is a cross-sectional view of an example of an optical module according to modification example 1 of the third embodiment.

FIG. 8 is a cross-sectional view of an example of an optical module according to modification example 2 of the third embodiment.

FIG. 9 is a cross-sectional view of an example of an optical module according to a fourth embodiment.

FIG. 10A is a diagram (part 1) illustrating an example of the manufacturing process of the optical module according to the fourth embodiment.

FIG. 10B is a diagram (part 2) illustrating an example of the manufacturing process of the optical module according to the fourth embodiment.

FIG. 10C is a diagram (part 3) illustrating an example of the manufacturing process of the optical module according to the fourth embodiment.

FIG. 10D is a diagram (part 4) illustrating an example of the manufacturing process of the optical module according to the fourth embodiment.

FIG. 11 is a cross-sectional view of an example of an optical module according to modification example 1 of the fourth embodiment.

FIG. 12 is a cross-sectional view of an example of an optical module according to modification example 2 of the fourth embodiment.

FIG. 13 is a cross-sectional view of an example of an optical module according to a fifth embodiment.

FIG. 14 is a cross-sectional view of an example of an optical module according to modification example 1 of the fifth embodiment.

FIG. 15 is a cross-sectional view of an example of a module according to a sixth embodiment.

### DESCRIPTION OF EMBODIMENTS

Hereinafter, embodiments for carrying out the invention will be described with reference to the drawings. In the drawings, the same reference numerals are applied to the same constituent parts, and redundant descriptions may be omitted.

### First Embodiment

### Structure of Optical Module

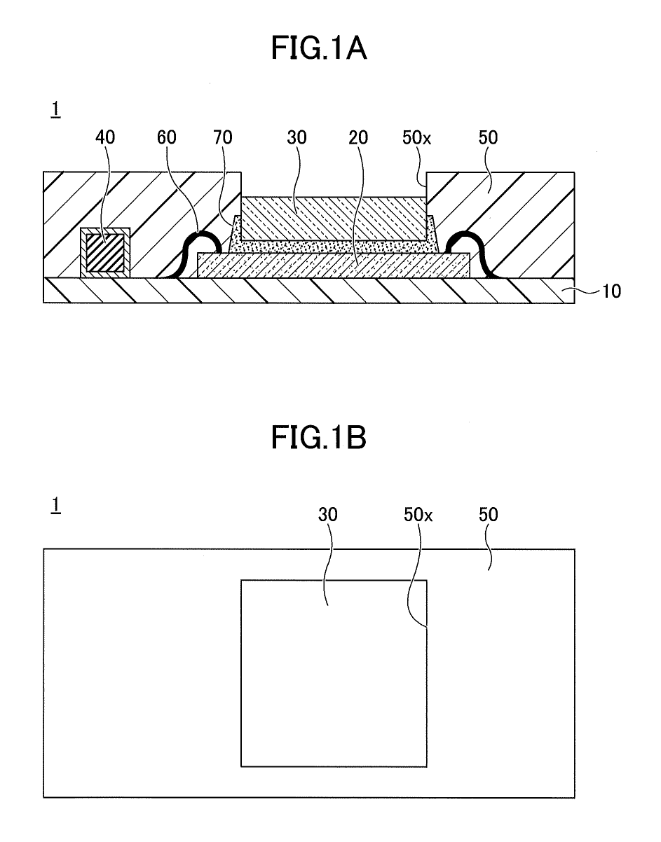

FIG. 1A is a cross-sectional view of an example of an optical module according to a first embodiment. FIG. 1B is a plan view of an example of the optical module according to the first embodiment. Referring to FIGS. 1A and 1B, an optical module 1 according to a first embodiment includes a wiring substrate 10, a light-receiving element 20, a light-transmitting body 30, an electronic component 40, a light-shielding resin 50, a metal wire 60, and a translucent adhesive 70. Note that the light-transmitting body 30 is a representative example of a first light-transmitting body according to the present invention. Each component will be described below.

The wiring substrate 10 is a portion to serve as a base for mounting the light-receiving element 20, etc. For example, a so-called glass epoxy substrate, in which an insulating resin such as an epoxy-based resin is impregnated in a glass cloth, may be used. As the wiring substrate 10, for example, a ceramic substrate and a silicon substrate, etc., may be used. Furthermore, the wiring substrate 10 may be a multilayer wiring substrate such as a buildup substrate. The thickness of the wiring substrate 10 may be, for example, approximately 100 μm to 300 μm.

Note that in the case where the wiring substrate 10 has a plurality of wiring layers, it is preferable that the difference in the remaining copper rate between the wiring layers, is small. This is to reduce the warpage of the wiring substrate 10.

The light-receiving element 20 is, for example, a photodiode or an image sensor, etc., and is mounted on the upper surface of the wiring substrate 10. The light-receiving element 20 is electrically connected to a pad (not illustrated) formed on the wiring substrate 10, for example, by the metal wire 60 (bonding wire) that is a gold wire or a copper wire, etc. The thickness of the light-receiving element 20 may be, for example, approximately 30 μm to 1000 μm. Note that the surface of the light-receiving element 20, on the side opposite to the wiring substrate 10 (the upper surface in FIGS. 1A and 1B), is the light-receiving surface.

It is preferable that the region, in which the light-receiving element 20 is mounted on the upper surface of the wiring substrate 10, is flat. For example, it is possible to form a solid copper foil, without forming wirings and through holes, in the region where the light-receiving element 20 is mounted on the upper surface of the wiring substrate 10.

The light-transmitting body 30 is mounted on the light-receiving surface of the light-receiving element 20 via the translucent adhesive 70. Note that in the present application, the light-receiving surface of the light-receiving element may be referred to as the upper surface of the light-receiving element in some cases. Similarly, the light-emitting surface of a light-emitting element may be referred to as the upper surface of the light-emitting element. Furthermore, the upper surface of the optical element refers to the light-receiving surface in the case of a light-receiving element, and the light-emitting surface in the case of a light-emitting element.

As the light-transmitting body 30, for example, borosilicate glass, etc., may be used. The thickness of the light-transmitting body 30 may be, for example, approximately 100 μm to 1 mm. As the translucent adhesive 70, for example, a silicone-based or epoxy-based optical adhesive containing no filler may be used. The thickness of the translucent adhesive 70 may be, for example, approximately 3 μm to 1000 μm. The light attenuation factor of the translucent adhesive 70 is preferably less than 10%.

Note that it is preferable that a fillet of the translucent adhesive 70 is formed on the side surface of the light-transmitting body 30. This is for the purpose of reducing voids generated in the translucent adhesive 70 and improving the adhesive bonding strength of the light-transmitting body 30 to the light-receiving surface of the light-receiving element 20.

The electronic component 40 is mounted on the upper surface of the wiring substrate 10. The electronic component 40 may be an active component part such as a transistor or an IC, or may be a passive component part such as a resistor or a capacitor. Alternatively, an active component part and a passive component part may be mixed. Note that the electronic component 40 may be mounted only when necessary.

The light-shielding resin 50 is provided on the upper surface of the wiring substrate 10 so as to cover the side surface portions of the light-receiving element 20 and the light-transmitting body 30, and the electronic component 40. As the light-shielding resin 50, for example, an epoxy-based insulating resin, etc., having excellent rigidity, may be used. The light-shielding resin 50 contains filler such as silica or alumina.

The upper surface of the light-shielding resin 50 is a ground surface (a surface that has undergone grinding), and the ground surface of the filler is exposed on the upper surface of the light-shielding resin 50. Note that the upper surface of the light-shielding resin 50 is a ground surface, and, therefore, the entire upper surface of the light-shielding resin 50, including the ground surface of the filler exposed on the upper surface of the light-shielding resin 50, is a flat surface. The surface roughness of the upper surface of the light-shielding resin 50 may be, for example, approximately Ra 0.1 μm to 50 μm.

In the optical module 1, the upper surface of the light-transmitting body 30 is at a position lower than the upper surface of the light-shielding resin 50. In a plan view, the upper surface of the light-shielding resin 50 is positioned around the upper surface of the light-transmitting body 30. That is, a recessed portion 50x is formed on the upper surface side of the light-transmitting body 30. The depth of the recessed portion 50x may be, for example, approximately 20 μm to 100 μm.

### Method of Manufacturing Optical Module

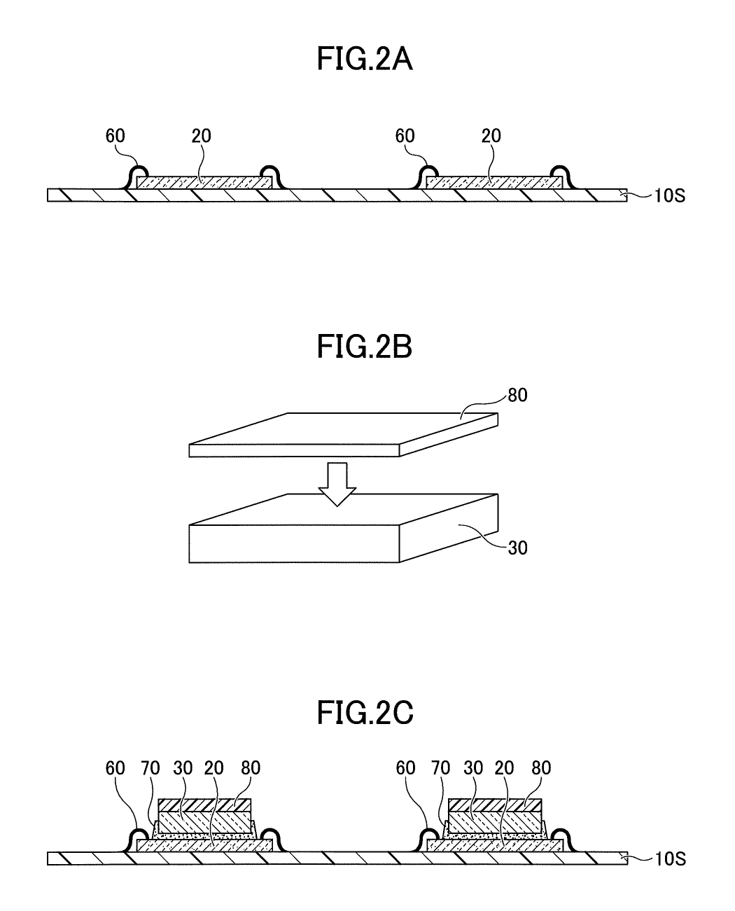

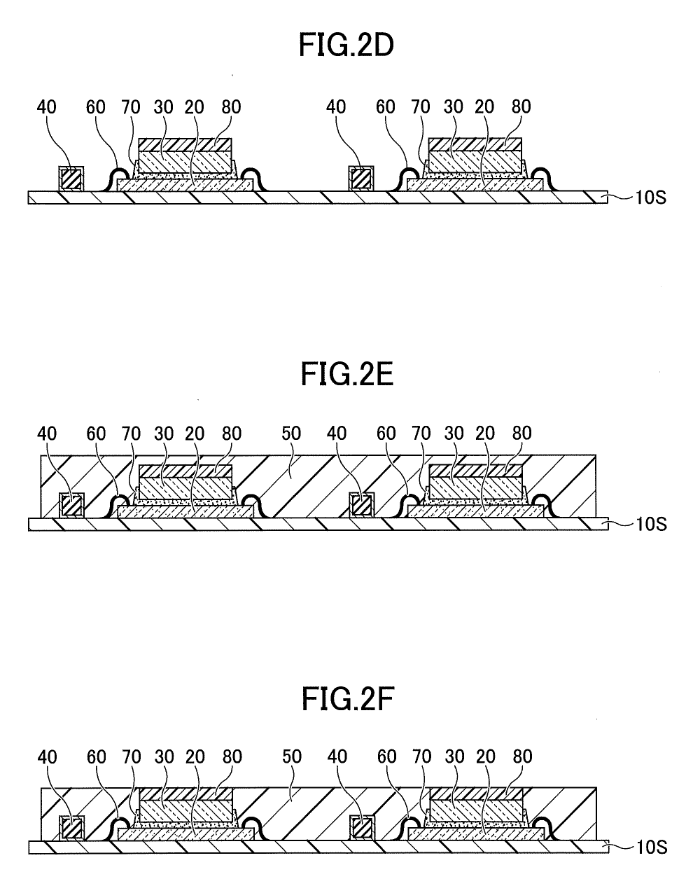

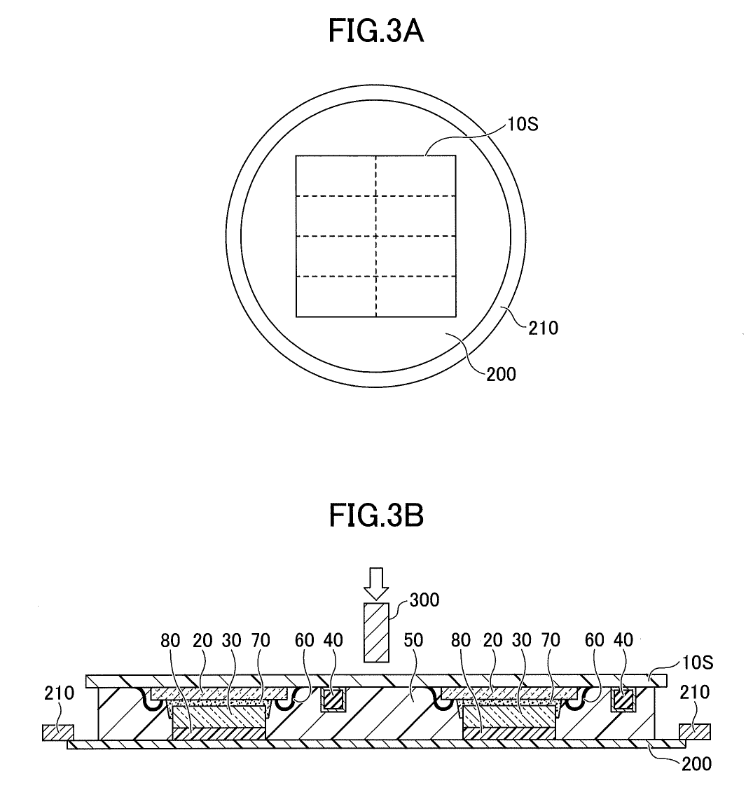

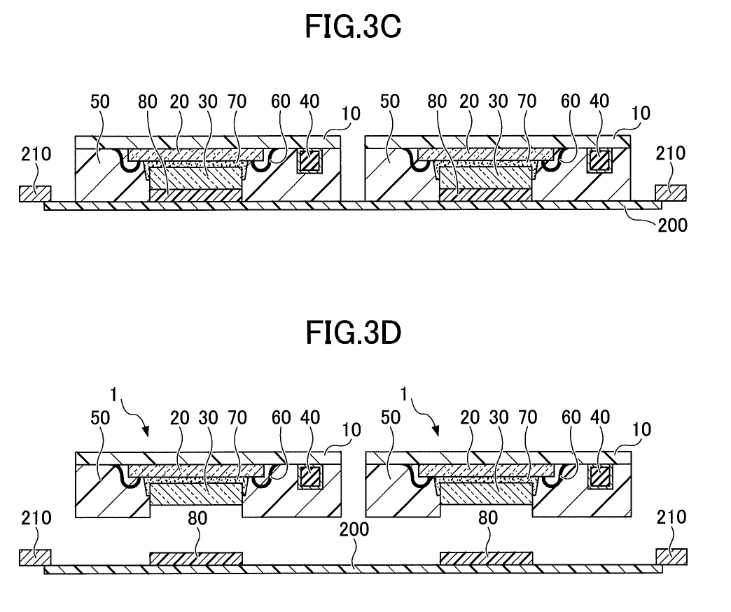

Next, a method of manufacturing the optical module 1 will be described. FIGS. 2A to 2F and FIGS. 3A to 3D are diagrams illustrating an example of the processes of manufacturing the optical module according to the first embodiment.

First, in a process illustrated in FIG. 2A, a sheet substrate 10S, in which a plurality of regions to be the wiring substrates 10 are defined, is prepared, and the light-receiving element 20 is mounted in each region to be the wiring substrate 10. The light-receiving element 20 may be mounted by, for example, a die bonder. Then, the light-receiving element 20 is electrically connected (by wire bonding) to a pad (not illustrated) formed in each region, with the metal wire 60 (bonding wire) that is gold wire or copper wire, etc.

Next, in the process illustrated in FIG. 2B, a plurality of the light-transmitting bodies 30 are prepared, and a protective sheet 80 is adhered onto the upper surface of each light-transmitting body 30. As the protective sheet 80, for example, a polyimide tape, etc., may be used. The thickness of the protective sheet 80 may be, for example, approximately 20 μm to 100 μm.

Note that a sheet-shaped light-transmitting body, in which a plurality of regions to be the light-transmitting bodies 30 are defined, may be prepared, the protective sheet 80 may be adhered onto the sheet-shaped light-transmitting body, and then the protective sheet 80 and the light-transmitting body 30 may be divided in to individual pieces, to fabricate a plurality of the light-transmitting bodies 30 to which the protective sheet 80 is adhered. Furthermore, as the protective sheet 80, instead of using a polyimide tape, etc., for example, a liquid silicone resin, etc., may be spin-coated on the sheet-like light-transmitting body and then the light-transmitting body may be cured. Furthermore, after forming the light-transmitting body 30, the protective sheet 80 may be adhered.

Next, in the process illustrated in FIG. 2C, the translucent adhesive 70 is applied to the light-receiving surface of each light-receiving element 20. Then, the light-transmitting body 30, to which with the protective sheet 80 is adhered, is mounted on the translucent adhesive 70 so that the protective sheet 80 faces upward. Then, the light-transmitting body 30 is pressed from the side having the protective sheet 80, so that the light-transmitting body 30 is bonded onto the light-receiving surface of each light-receiving element 20. The translucent adhesive 70 may be applied, for example, with a dispenser. The light-transmitting body 30, to which the protective sheet 80 has been adhered, may be mounted by, for example, a die bonder.

Note that it is preferable that the surfaces of the light-transmitting body 30 to be bonded onto the translucent adhesive 70 (the bottom surface and the side surfaces of the light-transmitting body 30) are subjected to silane coupling treatment or plasma treatment before bonding. This is for improving the adhesive bonding strength between the light-transmitting body 30 and the translucent adhesive 70.

Next, in the process illustrated in FIG. 2D, the electronic component 40 is mounted in each region of the sheet substrate 10S to be the wiring substrate 10. The electronic component 40 may be mounted by using, for example, a chip mounter and a reflow device. Furthermore, the sheet substrate 10S, in which a plurality of regions to be the wiring substrates 10 are defined, may be prepared, and the electronic component 40 may be mounted on the sheet substrate 10S, before mounting the light-receiving element 20 in each region to be the wiring substrate 10.

Next, in the process illustrated in FIG. 2E, the light-receiving element 20, the light-transmitting body 30 including the protective sheet 80, and the electronic component 40, are covered with the light-shielding resin 50. The process of covering these components with the light-shielding resin 50 may be performed, for example, by a compression molding method. In this case, it is preferable to set the molding temperature to less than 180° C., and to set the molding pressure to less than 60 kgf.

Under these conditions, it is possible to reduce the stress applied on the light-transmitting body 30 and the translucent adhesive 70 at the time of molding, and to prevent peeling and breakage between the light-transmitting body 30 and the translucent adhesive 70. Furthermore, in the compression molding method, the flow velocity of the resin is low, and, therefore, the load on the extremely fine metal wire 60 is small, and deformation of the metal wire 60 due to resin flow can be prevented.

Next, in the process illustrated in FIG. 2F, the upper surface of the light-shielding resin 50 is subjected to grinding until the upper surface of the protective sheet 80 is exposed. The grinding may be performed by using, for example, a back grinder, etc. The upper surface of the light-shielding resin 50 after grinding is substantially flush with the upper surface of the protective sheet 80.

In this process, the upper surface of the light-shielding resin 50 becomes a ground surface, and the ground surface of the filler is exposed on the upper surface of the light-shielding resin 50. Note that the upper surface of the light-shielding resin 50 is a ground surface, and, therefore, the entire upper surface of the light-shielding resin 50, including the ground surface of the filler exposed on the upper surface of the light-shielding resin 50, is a flat surface. The surface roughness of the upper surface of the light-shielding resin 50 may be, for example, approximately Ra 0.1 μm to 50 μm.

Next, in the process illustrated in FIG. 3A, a substrate fixing tape 200, in which an annular wafer ring 210 is provided on the outer peripheral portion, is prepared. Then, the structure illustrated in FIG. 2F is mounted (temporarily fixed) on the substrate fixing tape 200 inside the wafer ring 210 with the protective sheet 80 facing the substrate fixing tape 200 side.

Next, in the processes illustrated in FIGS. 3B and 3C, a plurality of regions to be the optical modules 1 are divided into individual pieces by using a blade 300, and the respective structures are made independent.

Next, in the process illustrated in FIG. 3D, each structure illustrated in FIG. 3C is peeled from the substrate fixing tape 200. At this time, the adhesive strength between the light-transmitting body 30 and the protective sheet 80 is smaller than the adhesive strength between the protective sheet 80 and the substrate fixing tape 200, and, therefore, the interface between the light-transmitting body 30 and the protective sheet 80 peels off and the protective sheet 80 is removed from the light-transmitting body 30. Accordingly, a plurality of optical modules 1 is fabricated.

Note that using a transparent member as the protective sheet 80 is preferable because in the process illustrated in FIG. 2C, the process illustrated in FIG. 2D, and the process illustrated in FIG. 2F, the appearance of the light-receiving surface of the light-receiving element 20 can be visually observed through the transparent protective sheet 80.

In this manner, in the optical module 1, the upper surface of the light-shielding resin 50 is a ground surface, and, therefore, the optical module 1 is excellent in terms of flatness. Therefore, for example, when incorporating the optical module 1 into a camera module, it is possible to directly mount a lens module, etc., on the upper surface (ground surface) of the light-shielding resin 50 of the optical module 1. Furthermore, the light-shielding resin 50 contains filler, and, therefore, it is possible to realize the optical module 1 having excellent mechanical strength and moisture resistance.

Furthermore, in the optical module 1, the upper surface of the light-transmitting body 30 is at a position lower than the upper surface of the light-shielding resin 50. Therefore, for example, when the optical module 1 is used for a camera module, it is possible to prevent flare or ghosting, in which the light-shielding resin 50 around the light-transmitting body 30 is reflected on the light-receiving surface of the light-receiving element 20.

### Second Embodiment

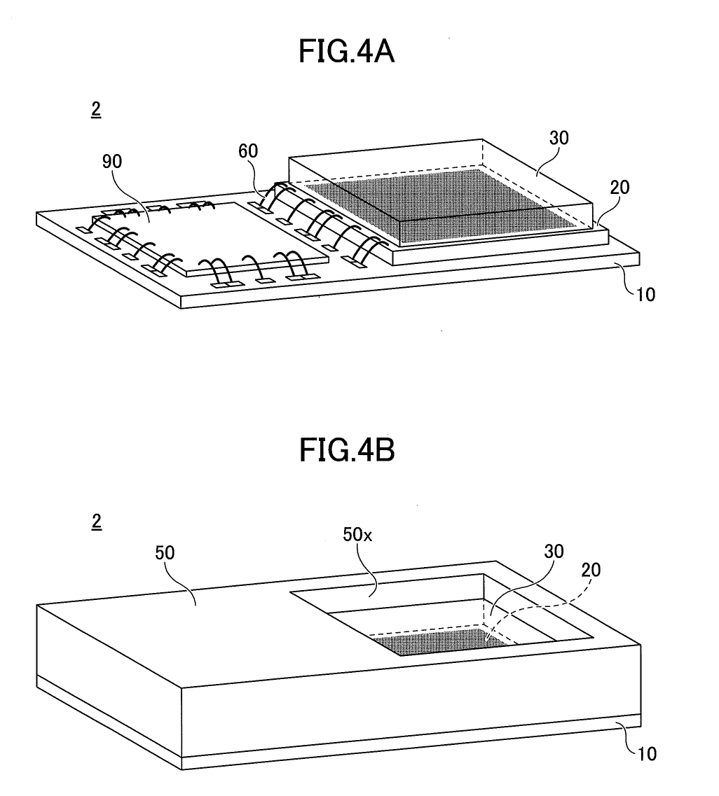

FIGS. 4A and 4B are perspective views illustrating an example of the optical module according to a second embodiment. FIG. 4A illustrates a semi-finished state before being sealed with the light-shielding resin 50, and FIG. 4B illustrates completed state after being sealed with the light-shielding resin 50.

Referring to FIGS. 4A and 4B, an optical module 2 according to the second embodiment is different from the optical module 1 (see FIGS. 1A and 1B) in that a semiconductor element 90 is mounted as an electronic component. The light-receiving element 20 is, for example, a photodiode, and the semiconductor element 90 is, for example, an integrated circuit that performs analog signal processing on an electric signal that has been photoelectrically converted by the light-receiving element 20.

With such a structure, for example, a photodiode multi-chip module can be realized. Note that the optical module 2 can be fabricated by the same manufacturing processes as the optical module 1.

In the optical module 2 as well, similar to the optical module 1, the upper surface of the light-shielding resin 50 is a ground surface, and is thus excellent in flatness. Therefore, for example, when incorporating the optical module 2 into a camera module, it is possible to directly mount a lens module, etc., on the upper surface (ground surface) of the light-shielding resin 50 of the optical module 2. Furthermore, the light-shielding resin 50 contains filler, and, therefore, it is possible to realize the optical module 2 having excellent mechanical strength and moisture resistance.

Furthermore, in the optical module 2 as well, similar to the optical module 1, the upper surface of the light-transmitting body 30 is at a position lower than the upper surface of the light-shielding resin 50. Therefore, for example, when the optical module 2 is used for a camera module, it is possible to prevent flare or ghosting, in which the light-shielding resin 50 around the light-transmitting body 30 is reflected on the light-receiving surface of the light-receiving element 20.

### Third Embodiment

In a third embodiment, an example of an optical module on which a light-transmitting body that is different from that of the first embodiment is mounted, is described. Note that in the third embodiment, descriptions of the same constituent parts as in the previously described embodiments may be omitted.

### Structure of Optical Module

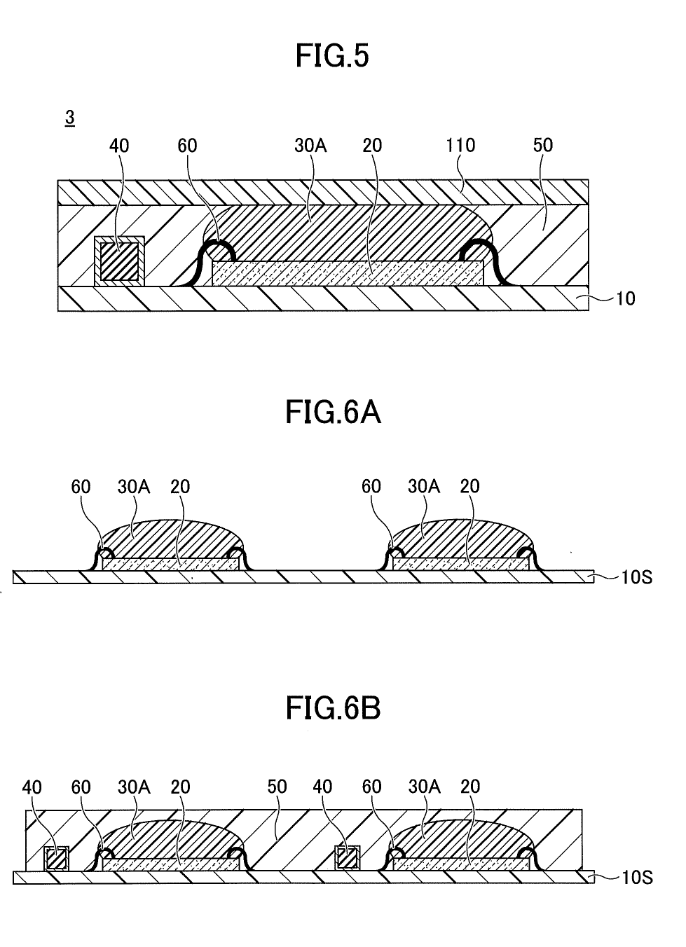

FIG. 5 is a cross-sectional view of an example of the optical module according to the third embodiment. Note that the plan view is similar to that of FIG. 1B, and, therefore, illustration of the plan view is omitted. Referring to FIG. 5, an optical module 3 according to the third embodiment is different from the optical module 1 (see FIGS. 1A and 1B) in that the light-transmitting body 30 is replaced by a light-transmitting body 30A, the translucent adhesive 70 is not provided, and a translucent protective film 110 is provided. Note that the light-transmitting body 30A is a representative example of the first light-transmitting body according to the present invention and the translucent protective film 110 is a representative example of a second light-transmitting body according to the present invention.

The light-transmitting body 30A is directly mounted on the light-receiving surface of the light-receiving element 20. The side surface of the light-transmitting body 30A may be, for example, a curved surface. As the light-transmitting body 30A, for example, a silicone-based or epoxy-based optical resin not containing filler, may be used. The thickness of the light-transmitting body 30A may be, for example, approximately 100 μm to 1 mm. The light attenuation factor of the light-transmitting body 30A is preferably less than 10%.

The translucent protective film 110 is formed so as to continuously cover the upper surface of the light-transmitting body 30A and the upper surface of the light-shielding resin 50. The translucent protective film 110 is formed of a material (material having a high barrier property) having a lower moisture and oxygen permeability than the light-transmitting body 30A. Accordingly, it is possible to prevent white turbidity of the light-transmitting body 30A due to oxygen, and corrosion of the light-receiving element 20 due to moisture, etc.

Specifically, for example, a silicone-based resin may be used as the translucent protective film 110. The thickness of the translucent protective film 110 is preferably approximately 10 μm to 100 μm.

### Method of Manufacturing Optical Module

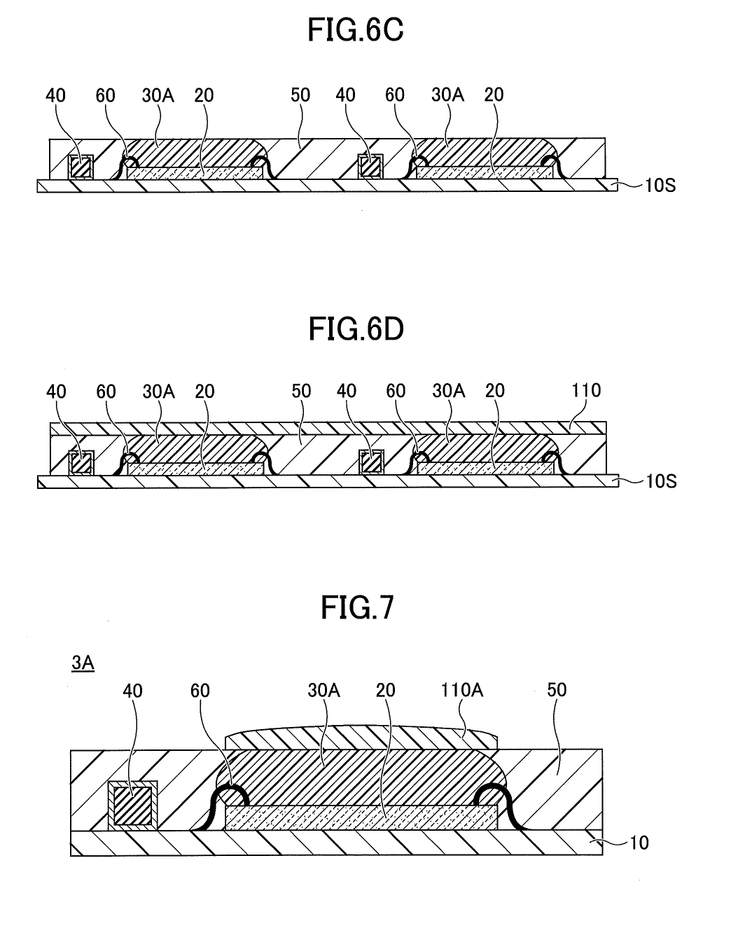

Next, a method of manufacturing the optical module 3 will be described. FIGS. 6A to 6D are diagrams illustrating an example of the manufacturing process of the optical module according to the third embodiment.

First, after performing the same process as in FIG. 2A, in the process illustrated in FIG. 6A, the light-transmitting body 30A formed of uncured optical resin is disposed on the light-receiving surface of each light-receiving element 20. In the light-transmitting body 30A, for example, a liquid or pasty optical resin may be applied on the light-receiving surface of each light-receiving element 20 with a dispenser. Alternatively, an uncured film-like optical resin may be laminated on the light-receiving surface of each light-receiving element 20.

Note that the light-transmitting body 30A may be formed into any shape such as a dome shape. Furthermore, the uncured light-transmitting body 30A has adhesive bonding properties, and, therefore, the translucent adhesive 70 is unnecessary when mounting the light-transmitting body 30A on the light-receiving element 20.

Next, in the process illustrated in FIG. 6B, the light-transmitting body 30A is cured by heating or ultraviolet irradiation, etc., and then, similar to the process illustrated in FIG. 2D, the electronic component 40 is mounted in each region to be the wiring substrate 10 of the sheet substrate 10S. Furthermore, similar to the process illustrated in FIG. 2E, the light-receiving element 20, the light-transmitting body 30A, and the electronic component 40 are covered with the light-shielding resin 50. However, the sheet substrate 10S, in which a plurality of regions to be the wiring substrates 10 are defined, may be prepared, and the electronic component 40 may be mounted on the sheet substrate 10S, before mounting the light-receiving element 20 in each region to be the wiring substrate 10. Furthermore, specific methods and conditions for covering the components with the light-shielding resin 50 are as described above.

Next, in the process illustrated in FIG. 6C, the upper surface of the light-shielding resin 50 is subjected to grinding until the necessary area of the upper surface of the light-transmitting body 30A is exposed. The grinding may be performed by using, for example, a back grinder, etc. The upper surface of the light-shielding resin 50 after grinding is substantially flush with the upper surface of the light-transmitting body 30A. Note that the necessary area of the upper surface of the light-transmitting body 30A is, for example, an area larger than the area of the light-receiving section of the light-receiving element 20.

In this process, the upper surface of the light-shielding resin 50 becomes a ground surface, and the ground surface of the filler is exposed on the upper surface of the light-shielding resin 50. Note that the upper surface of the light-shielding resin 50 is a ground surface, and, therefore, the entire upper surface of the light-shielding resin 50 including the ground surface of the filler exposed on the upper surface of the light-shielding resin 50, is a flat surface. The surface roughness of the upper surface of the light-shielding resin 50 may be, for example, approximately Ra 0.1 μm to 50 μm.

Next, in the process illustrated in FIG. 6D, the translucent protective film 110 is formed by, for example, an application method or a resin sealing method so as to continuously cover the upper surface of the light-transmitting body 30A and the upper surface of the light-shielding resin 50. After the process illustrated in FIG. 6D, similar to the processes illustrated in FIGS. 3A to 3D, the structure illustrated in FIG. 6D is divided in to individual pieces. Accordingly, a plurality of the optical modules 3 is fabricated.

Also in the optical module 3, similar to the optical module 1, the light-shielding resin 50 contains filler, and, therefore, it is possible to realize the optical module 3 having excellent mechanical strength and moisture resistance. Furthermore, the upper surface of the light-transmitting body 30A and the upper surface of the light-shielding resin 50 are covered with the translucent protective film 110, and, therefore, it is possible to prevent white turbidity of the light-transmitting body 30A due to oxygen, and corrosion of the light-receiving element 20 due to moisture, etc.

### Modification Example 1 of Third Embodiment

Modification example 1 of the third embodiment indicates an example in which the shape of the translucent protective film is different. Note that, in modification example 1 of the third embodiment, descriptions of the same constituent parts as in the previously described embodiments may be omitted.

FIG. 7 is a cross-sectional view of an example of an optical module according to modification example 1 of the third embodiment. Note that the plan view is similar to that of FIG. 1B, and, therefore, illustration of the plan view is omitted. Referring to FIG. 7, the optical module 3A according to modification example 1 of the third embodiment is different from the optical module 3 (see FIG. 5) in that the translucent protective film 110 is replaced with a translucent protective film 110A. Note that the translucent protective film 110A is a representative example of the second light-transmitting body according to the present invention.

The translucent protective film 110 illustrated in FIG. 5 covers the entire upper surface of the light-transmitting body 30A and the entire upper surface of the light-shielding resin 50, whereas the translucent protective film 110A illustrated in FIG. 7 covers the upper surface of the light-transmitting body 30A and a part of the upper surface of the light-shielding resin 50. The translucent protective film 110A is formed so as to cover at least a boundary line between the upper surface of the light-transmitting body 30A and the upper surface of the light-shielding resin 50. The material and the thickness of the translucent protective film 110A may be the same as, for example, those of the translucent protective film 110.

In order to form the translucent protective film 110A, in the process illustrated in FIG. 6D, the translucent protective film 110A is to be applied or laminated and cured, so as to cover at least the boundary line between the upper surface of the light-transmitting body 30A and the upper surface of the light-shielding resin 50. Alternatively, after the process illustrated in FIG. 6C, the structure illustrated in FIG. 6C may be divided in to individual pieces, and the translucent protective film 110A may be applied or laminated and cured, so as to cover at least the boundary line between the upper surface of the light-transmitting body 30A and the upper surface of the light-shielding resin 50, of each of the individual pieces of the divided structure.

Also in the optical module 3A, similar to the optical module 3, the light-shielding resin 50 contains filler, and, therefore, it is possible to realize the optical module 3A having excellent mechanical strength and moisture resistance. Furthermore, the translucent protective film 110A is formed so as to cover at least the boundary line between the upper surface of the light-transmitting body 30A and the upper surface of the light-shielding resin 50, and, therefore, similar to the optical module 3, it is possible to prevent white turbidity of the light-transmitting body 30A due to oxygen, and corrosion of the light-receiving element 20 due to moisture, etc.

### Modification Example 2 of Third Embodiment

Modification example 2 of the third embodiment indicates an example in which a translucent protective film is not provided. Note that in modification example 2 of the third embodiment, descriptions of the same constituent parts as in the previously described embodiments may be omitted.

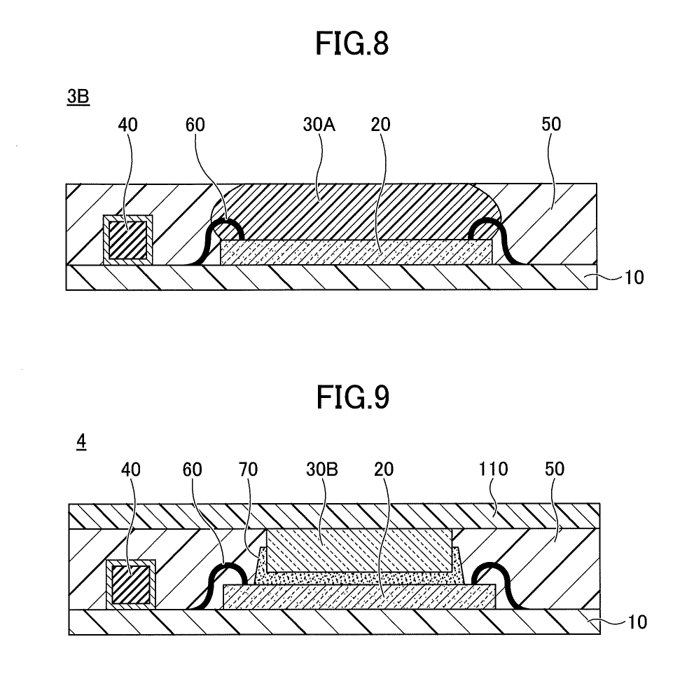

FIG. 8 is a cross-sectional view of an example of an optical module according to modification example 2 of the third embodiment. Note that the plan view is similar to that of FIG. 1B, and, therefore, illustration of the plan view is omitted. Referring to FIG. 8, an optical module 3B according to modification example 2 of the third embodiment is different from the optical module 3 (see FIG. 5) in that the translucent protective film 110 is not provided. In this manner, the translucent protective film 110 may be provided as necessary.

In the optical module 3B as well, similar to the optical module 1, the upper surface of the light-shielding resin 50 is a ground surface, and is thus excellent in flatness. Therefore, for example, when incorporating the optical module 3B into a camera module, it is possible to directly mount a lens module, etc., on the upper surface (ground surface) of the light-shielding resin 50 of the optical module 3B. Furthermore, the light-shielding resin 50 contains filler, and, therefore, it is possible to realize the optical module 3B having excellent mechanical strength and moisture resistance.

### Fourth Embodiment

In a fourth embodiment, an example of an optical module on which a light-transmitting body that is different from that of the third embodiment is mounted, is described. Note that in the fourth embodiment, descriptions of the same constituent parts as in the previously described embodiments may be omitted.

### Structure of Optical Module

FIG. 9 is a cross-sectional view of an example of the optical module according to the fourth embodiment. Note that the plan view is similar to that of FIG. 1B, and, therefore, illustration of the plan view is omitted. Referring to FIG. 9, an optical module 4 according to the fourth embodiment is different from the optical module 3 (see FIG. 5) in that the light-transmitting body 30A is replaced by a light-transmitting body 30B and the translucent adhesive 70 is provided. Note that the light-transmitting body 30B is a representative example of the first light-transmitting body according to the present invention.

The light-transmitting body 30B is mounted on the light-receiving surface of the light-receiving element 20 via the translucent adhesive 70. The side surface of the light-transmitting body 30B may be, for example, a flat surface. As the light-transmitting body 30B, for example, an optical resin molded article or glass, etc., may be used. The thickness of the light-transmitting body 30B may be, for example, approximately 100 μm to 1 mm.

Note that it is preferable that a fillet of the translucent adhesive 70 is formed on the side surface of the light-transmitting body 30B. This is for the purpose of reducing voids generated in the translucent adhesive 70 and improving the adhesive bonding strength of the light-transmitting body 30B to the light-receiving surface of the light-receiving element 20.

### Method of Manufacturing Optical Module

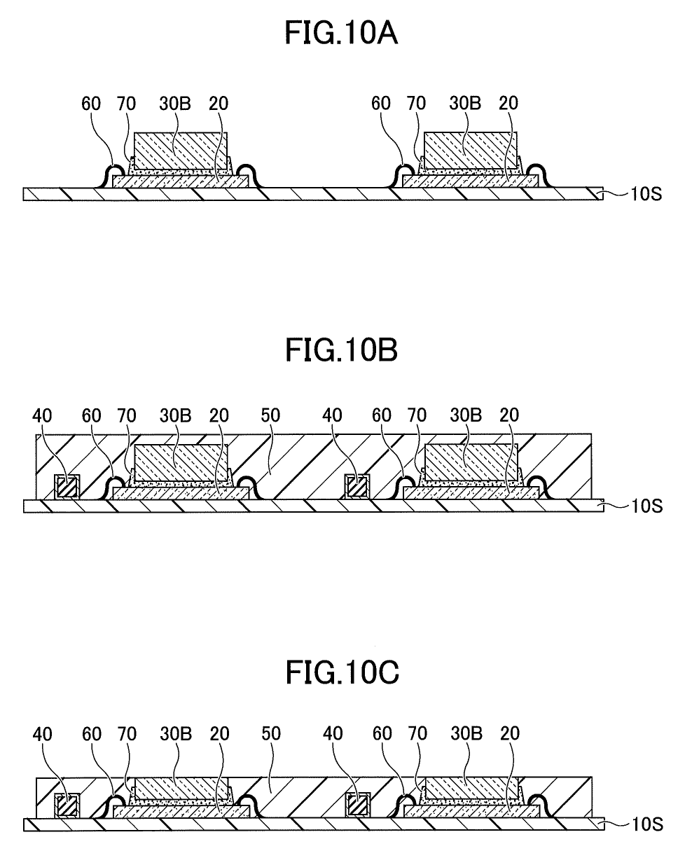

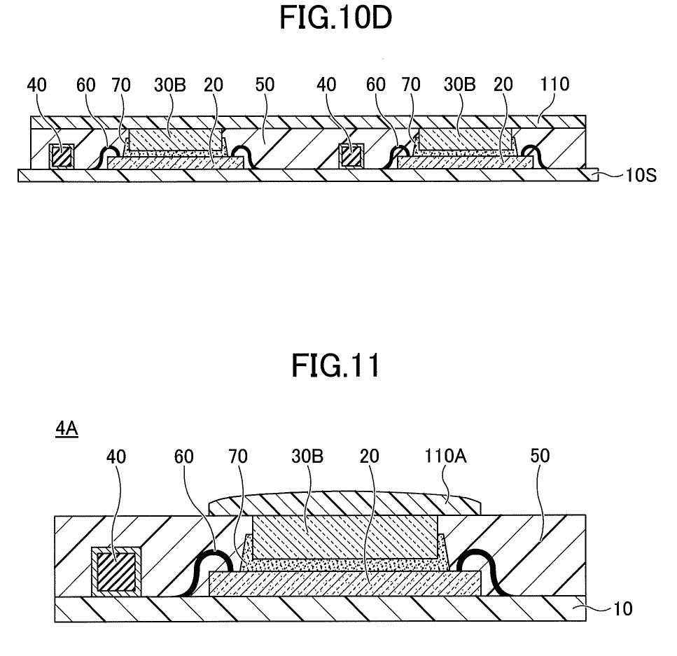

Next, a method of manufacturing the optical module 4 will be described. FIG. 10A to FIG. 10D are diagrams illustrating an example of the processes of manufacturing the optical module according to the fourth embodiment.

First, after performing a process similar to that illustrated in FIG. 2A, in the process illustrated in FIG. 10A, similar to the process illustrated in FIG. 2C, the translucent adhesive 70 is applied to the light-receiving surface of each light-receiving element 20, and the light-transmitting body 30B is mounted on the translucent adhesive 70. Then, the light-transmitting body 30B is pressed to bond the light-transmitting body 30B onto the light-receiving surface of each light-receiving element 20. Note that it is preferable that the surfaces of the light-transmitting body 30B to be bonded onto the translucent adhesive 70 (the bottom surface and the side surfaces of the light-transmitting body 30B) are subjected to silane coupling treatment or plasma treatment, before bonding. This is to improve the adhesive bonding strength between the light-transmitting body 30B and the translucent adhesive 70.

Next, in the process illustrated in FIG. 10B, after the translucent adhesive 70 is cured by heating or ultraviolet irradiation, etc., similar to the process illustrated in FIG. 2D, the electronic component 40 is mounted in each region to be the wiring substrate 10 on the sheet substrate 10S, and furthermore, similar to the process illustrated in FIG. 2E, the light-receiving element 20, the light-transmitting body 30B, the electronic component 40, and the translucent adhesive 70 are covered with the light-shielding resin 50. However, the sheet substrate 10S, in which a plurality of regions to be the wiring substrates 10 are defined, may be prepared, and the electronic component 40 may be mounted on the sheet substrate 10S, before mounting the light-receiving element 20 in each region to be the wiring substrate 10. Specific methods and conditions for covering the components with the light-shielding resin 50 are as described above.

Next, in the process illustrated in FIG. 10C, the upper surface of the light-shielding resin 50 is subjected to grinding until the upper surface of the light-transmitting body 30B is exposed. The grinding may be performed by using, for example, a back grinder, etc. The upper surface of the light-shielding resin 50 after grinding is substantially flush with the upper surface of the light-transmitting body 30B.

In this process, the upper surface of the light-shielding resin 50 becomes a ground surface, and the ground surface of the filler is exposed on the upper surface of the light-shielding resin 50. Note that the upper surface of the light-shielding resin 50 is a ground surface, and, therefore, the entire upper surface of the light-shielding resin 50, including the ground surface of the filler exposed on the upper surface of the light-shielding resin 50, is a flat surface. The surface roughness of the upper surface of the light-shielding resin 50 may be, for example, approximately Ra 0.1 μm to 50 μm.

Next, in the process illustrated in FIG. 10D, the translucent protective film 110 is formed by, for example, an application method or a resin sealing method so as to continuously cover the upper surface of the light-transmitting body 30B and the upper surface of the light-shielding resin 50. After the process illustrated in FIG. 10D, similar to the processes illustrated in FIGS. 3A to 3D, the structure illustrated in FIG. 10D is divided in to individual pieces. Accordingly, a plurality of the optical modules 4 is fabricated.

Also in the optical module 4, similar to the optical module 3, the light-shielding resin 50 contains filler, and, therefore, it is possible to realize the optical module 4 having excellent mechanical strength and moisture resistance. Furthermore, the upper surface of the light-transmitting body 30B and the upper surface of the light-shielding resin 50 are covered with the translucent protective film 110, and, therefore, it is possible to prevent white turbidity of the light-transmitting body 30B due to oxygen, and corrosion of the light-receiving element 20 due to moisture, etc.

### Modification Example 1 of Fourth Embodiment

Modification example 1 of the fourth embodiment indicates an example in which the shape of the translucent protective film is different. Note that, in modification example 1 of the fourth embodiment, descriptions of the same constituent parts as in the previously described embodiments may be omitted.

FIG. 11 is a cross-sectional view of an example of an optical module according to modification example 1 of the fourth embodiment. Note that the plan view is similar to that of FIG. 1B, and, therefore, illustration of the plan view is omitted. Referring to FIG. 11, in an optical module 4A according to modification example 1 of the fourth embodiment is different from the optical module 4 (see FIG. 9) in that the translucent protective film 110 is replaced with the translucent protective film 110A.

Similar to the optical module 3A illustrated in FIG. 7, the translucent protective film 110A illustrated in FIG. 11 covers the upper surface of the light-transmitting body 30B and a part of the upper surface of the light-shielding resin 50. The translucent protective film 110A is formed so as to cover at least a boundary line between the upper surface of the light-transmitting body 30B and the upper surface of the light-shielding resin 50.

Also in the optical module 4A, similar to the optical module 3A, the light-shielding resin 50 contains filler, and, therefore, it is possible to realize the optical module 4A having excellent mechanical strength and moisture resistance. Furthermore, the translucent protective film 110A is formed so as to cover at least the boundary line between the upper surface of the light-transmitting body 30B and the upper surface of the light-shielding resin 50, and, therefore, similar to the optical module 3A, it is possible to prevent white turbidity of the light-transmitting body 30B due to oxygen, and corrosion of the light-receiving element 20 due to moisture, etc.

### Modification Example 2 of Fourth Embodiment

Modification example 2 of the fourth embodiment indicates an example in which a translucent protective film is not provided. Note that, in modification example 2 of the fourth embodiment, descriptions of the same constituent parts as in the previously described embodiments may be omitted.

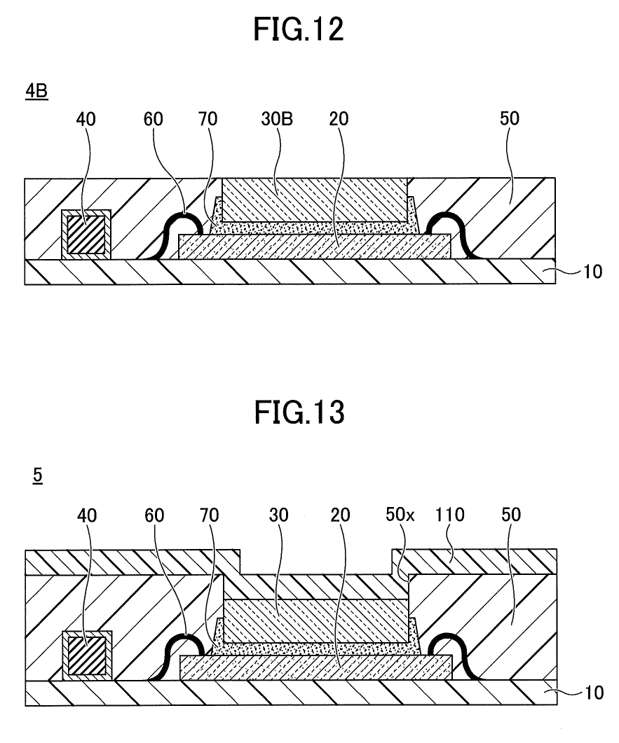

FIG. 12 is a cross-sectional view of an example of an optical module according to modification example 2 of the fourth embodiment. Note that the plan view is similar to that of FIG. 1B, and, therefore, illustration of the plan view is omitted. Referring to FIG. 12, an optical module 4B according to modification example 2 of the fourth embodiment is different from the optical module 4 (see FIG. 9) in that the translucent protective film 110 is not provided. In this manner, the translucent protective film 110 may be provided as necessary.

Also in the optical module 4B, similar to the optical module 1, the upper surface of the light-shielding resin 50 is a ground surface, and is thus excellent in flatness. Therefore, for example, when incorporating the optical module 4B into a camera module, it is possible to directly mount a lens module, etc., on the upper surface (ground surface) of the light-shielding resin 50 of the optical module 4B. Furthermore, the light-shielding resin 50 contains filler, and, therefore, it is possible to realize the optical module 4B having excellent mechanical strength and moisture resistance.

### Fifth Embodiment

In a fifth embodiment, an example in which a translucent protective film is provided in the optical module according to the first embodiment, is described. Note that in the fifth embodiment, descriptions of the same constituent parts as in the previously described embodiments may be omitted.

FIG. 13 is a cross-sectional view of an example of the optical module according to the fifth embodiment. Note that the plan view is similar to that of FIG. 1B, and, therefore, illustration of the plan view is omitted. Referring to FIG. 13, an optical module 5 according to the fifth embodiment is different from the optical module 1 (see FIGS. 1A and 1B) in that the translucent protective film 110 is provided.

The translucent protective film 110 is formed so as to continuously cover the upper surface of the light-transmitting body 30, the inner walls of the recessed portion 50x of the light-shielding resin 50, and the upper surface of the light-shielding resin 50. The translucent protective film 110 may be formed so as to completely fill the recessed portion 50x or so that a part of the recessed portion 50x remains.

Also in the optical module 5, similar to the optical module 1, the light-shielding resin 50 contains filler, and, therefore, it is possible to realize the optical module 5 having excellent mechanical strength and moisture resistance. Furthermore, the upper surface of the light-transmitting body 30, the inner walls of the recessed portion 50x of the light-shielding resin 50, and the upper surface of the light-shielding resin 50 are covered with the translucent protective film 110, and, therefore, it is possible to prevent white turbidity of the light-transmitting body 30 due to oxygen, and corrosion of the light-receiving element 20 due to moisture, etc.

### Modification Example 1 of Fifth Embodiment

Modification example 1 of the fifth embodiment indicates an example in which the shape of the translucent protective film is different. Note that, in modification example 1 of the fifth embodiment, descriptions of the same constituent parts as in the previously described embodiments may be omitted.

FIG. 14 is a cross-sectional view of an example of an optical module according to modification example 1 of the fifth embodiment. Note that the plan view is similar to that of FIG. 1B, and, therefore, illustration of the plan view is omitted. Referring to FIG. 14, an optical module 5A according to modification example 1 of the fifth embodiment is different from the optical module 5 (see FIG. 13) in that the translucent protective film 110 is replaced with the translucent protective film 110A.

Similar to the optical module 3A illustrated in FIG. 7 or the optical module 4A illustrated in FIG. 11, the translucent protective film 110A illustrated in FIG. 14 covers the upper surface of the light-transmitting body 30 and a part of the upper surface of the light-shielding resin 50. The translucent protective film 110A is formed so as to cover at least the boundary line between the upper surface of the light-transmitting body 30 and the upper surface of the light-shielding resin 50.

Also in the optical module 5A, similar to the optical modules 3A and 4A, the light-shielding resin 50 contains filler, and, therefore, it is possible to realize the optical module 5A having excellent mechanical strength and moisture resistance. Furthermore, the translucent protective film 110A is formed so as to cover at least the boundary line between the upper surface of the light-transmitting body 30 and the upper surface of the light-shielding resin 50, and, therefore, it is possible to prevent white turbidity of the light-transmitting body 30 due to oxygen, and corrosion of the light-receiving element 20 due to moisture, etc., similar to the optical modules 3A and 4A.

### Sixth Embodiment

In a sixth embodiment, an example in which a sensing device is mounted on a wiring substrate of the first embodiment will be described. Note that in the sixth embodiment, descriptions of the same constituent parts as in the previously described embodiments may be omitted.

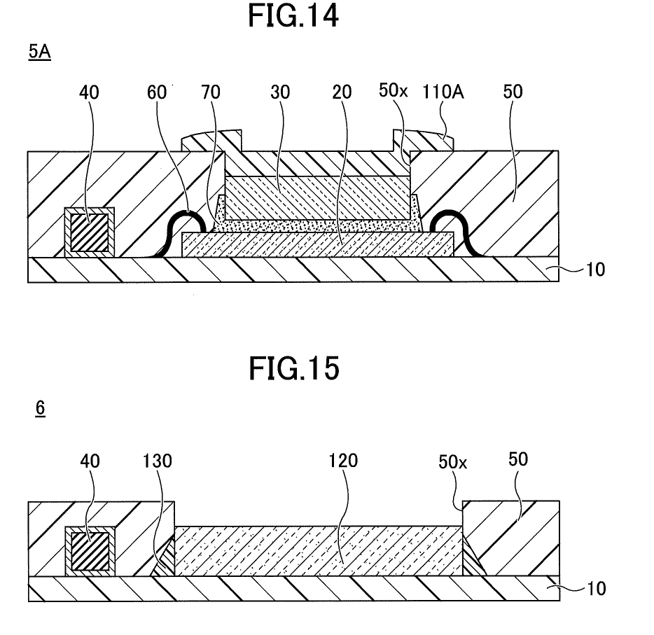

FIG. 15 is a cross-sectional view of an example of a module according to the sixth embodiment. Note that the plan view is similar to that of FIG. 1B, and, therefore, illustration of the plan view is omitted. Referring to FIG. 15, a module 6 according to the sixth embodiment is mainly different from the optical module 1 (see FIGS. 1A and 1B) in that the light-receiving element 20 is replaced with a sensing device 120.

The sensing device 120 is flip-chip mounted on the wiring substrate 10. Underfill resin 130 covers a joining portion (not illustrated) between the sensing device 120 and the wiring substrate 10 and a part of the side surface portion of the sensing device 120. The light-shielding resin 50 covers the remaining portions of the side surface portion of the sensing device 120. No light-transmitting body is provided on the sensing device 120.

The sensing device 120 is, for example, a device that detects any one of light, pressure, temperature, humidity, and gas. Note that when the sensing device 120 is not a device for detecting light, a light-shielding property is not required in the light-shielding resin 50, so a resin that does not have a light-shielding property may be used.

The module 6 may be fabricated in the same manner as in the first embodiment except that the sensing device 120 is flip-chip mounted in each region of the sheet substrate 10S to be the wiring substrate 10, in the process illustrated in FIG. 2A.

However, the method of mounting the sensing device 120 on the wiring substrate 10 is not limited to flip-chip mounting, and the same method (fixing with an adhesive and wire bonding) as in the first embodiment may be used.

Also in the module 6, similar to the optical module 1, the light-shielding resin 50 (or the resin not having a light shielding property) contains filler, and, therefore, it is possible to realize the module 6 having excellent mechanical strength and moisture resistance. Furthermore, the upper surface of the sensing device 120 is exposed, and, therefore, it is possible to directly sense an object to be detected.

Although the preferred embodiments have been described in detail above, the present invention is not limited to the above-described embodiments, and various modifications and substitutions may be made to the above-described embodiments without departing from the scope described in the claims.

For example, in the optical module according to each of the above-described embodiments, an example using a light-receiving element is illustrated; however, a light-emitting element may be used instead of the light-receiving element, and a light-transmitting body may be mounted on a light-emitting surface of the light-emitting element, directly or via a translucent adhesive. Examples of the light-emitting element include a laser diode and a light-emitting diode, etc. As described above, in the optical module according to the present invention, the light-transmitting body can be mounted on the upper surface (the light-receiving surface in the case of a light-receiving element, and the light-emitting surface in the case of a light-emitting element) of the optical element, directly or via a translucent adhesive.

Furthermore, a light-transmitting body may be provided so as to fill the recessed portion 50x of the light-shielding resin 50. As the light-transmitting body, a filter, etc., which transmits light of a predetermined wavelength band, etc., may be used. Alternatively, a resin, etc., having a moisture-proof effect may be used as the light-transmitting body. Note that even in these cases, the effect of preventing flare and ghosting remains unchanged.

The present application is based on and claims priority to Japanese Patent Application No. 2016-107497, filed on May 30, 2016, the contents of which are incorporated herein by reference in their entirety.

### REFERENCE SIGNS LIST

1, 2, 3, 3A, 3B, 4, 4A, 4B, 5, 5A optical module

6 module

10 wiring substrate

10S sheet substrate

20 light-receiving element

30, 30A, 30B light-transmitting body

40 electronic component

50 light-shielding resin

50x recessed portion

60 metal wire

70 translucent adhesive

80 protective sheet

90 semiconductor element

110, 110A translucent protective film

1. An optical module comprising:
a wiring substrate;
an optical element mounted on the wiring substrate;
a first light-transmitting body mounted on an upper surface of the optical element; and
a light-shielding resin covering the optical element and a side surface portion of the first light-transmitting body, wherein
the light-shielding resin includes filler, an upper surface of the light-shielding resin is a ground surface, and a ground surface of the filler is exposed on the upper surface of the light-shielding resin.

2. The optical module according to claim 1, wherein the first light-transmitting body is mounted on the upper surface of the optical element via a translucent adhesive.

3. The optical module according to claim 1, wherein the first light-transmitting body is formed of optical resin.

4. The optical module according to claim 1, wherein an upper surface of the first light-transmitting body is at a position lower than the upper surface of the light-shielding resin that is the ground surface.

5. The optical module according to claim 1, wherein a boundary line, between an upper surface of the first light-transmitting body and the upper surface of the light-shielding resin, is covered by a second light-transmitting body.

6. The optical module according to claim 1, wherein the optical element is a light-receiving element or a light-emitting element.

7. A module comprising:
a wiring substrate;
a sensing device mounted on the wiring substrate; and
a resin covering a side surface portion of the sensing device, wherein
the resin includes filler, an upper surface of the resin is a ground surface, and a ground surface of the filler is exposed on the upper surface of the resin.

8. The module according to claim 7, wherein the sensing device is a device configured to detect any one of light, pressure, temperature, humidity, and gas.

9. A method of manufacturing an optical module, the method comprising:
preparing a wiring substrate;
mounting an optical element on an upper surface the wiring substrate;
preparing a first light-transmitting body;
applying a translucent adhesive on an upper surface of the optical element;
mounting the first light-transmitting body on the translucent adhesive on the upper surface of the optical element, and pressing the first light-transmitting body to bond the first light-transmitting body onto the upper surface of the optical element;
covering the optical element and the first light-transmitting body with a light-shielding resin including filler; and
grinding the light-shielding resin until an upper surface of the first light-transmitting body is exposed.

10. The method of manufacturing the optical module according to claim 9, further comprising:
covering a boundary line, between the upper surface of the first light-transmitting body and an upper surface of the light-shielding resin, with a second light-transmitting body.

11. A method of manufacturing an optical module, the method comprising:
preparing a wiring substrate;
mounting an optical element on an upper surface the wiring substrate;
preparing a first light-transmitting body in which a protective sheet is provided on an upper surface of the first light-transmitting body;
applying a translucent adhesive on an upper surface of the optical element;
mounting the first light-transmitting body on the translucent adhesive on the upper surface of the optical element, and pressing the first light-transmitting body from a side with the protective sheet, to bond the first light-transmitting body onto the upper surface of the optical element;
covering the optical element and the first light-transmitting body having the protective sheet, with a light-shielding resin including filler;
grinding the light-shielding resin until an upper surface of the protective sheet is exposed; and
peeling off the protective sheet from the first light-transmitting body.

12. The method of manufacturing the optical module according to claim 11, further comprising:
covering a boundary line, between the upper surface of the first light-transmitting body and an upper surface of the light-shielding resin, with a second light-transmitting body.

13. A method of manufacturing an optical module, the method comprising:
preparing a wiring substrate;
mounting an optical element on an upper surface the wiring substrate;
forming a first light-transmitting body by applying an optical resin on an upper surface of the optical element;
covering the optical element and the first light-transmitting body with a light-shielding resin including filler; and
grinding the light-shielding resin until the upper surface of the first light-transmitting body is exposed.

14. The method of manufacturing the optical module according to claim 13, further comprising:
covering a boundary line, between an upper surface of the first light-transmitting body and an upper surface of the light-shielding resin, with a second light-transmitting body.

15. The method of manufacturing the optical module according to claim 9, wherein the optical element is a light-receiving element or a light-emitting element.

16. A method of manufacturing an optical module, the method comprising:
preparing a wiring substrate;
preparing a sensing device in which a protective sheet is provided on an upper surface of the sensing device;
mounting the sensing device on an upper surface of the wiring substrate such that an upper surface of the protective sheet is facing upwards;
covering the sensing device having the protective sheet, with a resin including filler;
grinding the resin until the upper surface of the protective sheet is exposed; and
peeling off the protective sheet from the sensing device.
